(19) United States
(12) Patent Application Publication
(10) Pub. No.: US 2025/0085480 A1
(43) Pub. Date: Mar. 13, 2025

(54) A CAVITY-ENHANCED WAVEGUIDE PHOTODETECTOR

(71) Applicant: ADVANCED MICRO FOUNDRY PTE. LTD., Singapore (SG)

(72) Inventors: Yanikgonul SALIH, Singapore (SG); Xianshu LUO, Singapore (SG)

(73) Assignee: ADVANCED MICRO FOUNDRY PTE. LTD., Singapore (SG)

(21) Appl. No.: 18/728,155

(22) PCT Filed: Mar. 1, 2022
(86) PCT No.: PCT/SG2022/050100

§ 371 Date: Jul. 11, 2024

(51) Int. Cl. G02B 6/293; G02B 6/12; H01L 31/0232; H01L 31/105

(52) U.S. Cl. CPC G02B 6/29379; H10F 30/223; H10F 77/413; G02B 6/12; G02B 2006/12123

(57) ABSTRACT

An integrated cavity-enhanced photodetector for visible photonics is provided. The photodetector includes a waveguide, an absorption layer, a set of metal contacts and a phase shifter. The photodetector can be used for visible photonics with multi-material integration flow and low loss.

### FIELD OF THE INVENTION

The present invention generally relates to a photodetector and particularly relates to an integrated cavity-enhanced photodetector for visible photonics with multi-material integration flow and low loss.

### BACKGROUND

This section is intended only to provide background information pertaining to the similar field of the present invention and may be used only to enhance the understanding of the present invention and not as admissions of prior art.

Silicon is indispensable for photonics applications in the telecommunication wavelengths. It is also the material of choice for visible light detection due to its high absorptivity. However, the very same high absorptivity of silicon renders itself not suitable for low-loss waveguiding of visible light. Therefore, a multi-material integration flow is needed to realize low-loss photonic components together with efficient photodetection for visible light. However, achieving a low-loss coupling and high responsivity detection of visible light in such hybrid photonics platform, without compromising the device speed, is a challenge.

Some solutions have been proposed in the prior art. Silicon Nitride (SiN)-on-Silicon-on-Insulator (SOI) and SiN-on-Silicon Dioxide (SiO₂)-on-Silicon (Si) photonic integrated circuits (PICs) are the prominent photonic platforms operating at visible/near-infrared (VIS/NIR) bands. The hybrid photonic devices that use grating structures, in-/intra-layer evanescent couplers, and end-fire butt-couplers to transfer light from waveguiding material into the absorbing material have also been developed. The grating-assisted coupling schemes are used to couple normally-incident light into the absorbing waveguide material through lateral diffraction of light, and they increase the optical penetration depth for a given absorbing film thickness. For configurations where the input light propagates within a waveguide, a design with two interlayer grating couplers is used to couple light between different layers. However, the photodetection has yet to be shown using this scheme, and moreover, the fabrication of double grating structure requires stringent process control to achieve vertical and horizontal alignment of two grating couplers at different layers.

The end-fire coupling schemes may suffer from high insertion loss on the coupling interface due to surface scattering and Fresnel reflections. In addition, the integration flow for same-layer SiN and Si deposition is not compatible with standard CMOS process. On the other hand, the evanescently coupled photodetectors require very long coupling lengths to achieve efficient optical coupling between waveguides because the optical mode is more confined inside the waveguide core at visible wavelengths, making the evanescent tail much weaker as compared to longer telecom wavelengths. This eventually sets a trade-off between responsivity and bandwidth. The responsivity can be increased via resonance cavity enhancement of the optical field at photoabsorption region, and such cavity-enhanced photodetectors have recently been reported in the literature.

A related work, as illustrated in FIG. 1A-C, integrates a SiN microring resonator (MRR) with a Si metal-semiconductor-metal (MSM) PD in-plane for NIR operation, and it significantly enhances the responsivity. However, the device of FIG. 1A-C suffers from low optical-electrical (OE) bandwidth of 7.5 GHz due to transit-time limitation of charge carriers. Since the charge carrier transport axis in this device is parallel to the light propagation direction, a longer device to improve the responsivity also leads to prolonged charge transport time, eventually limiting its OE bandwidth. It is well known that MSM PDs can operate with OE bandwidths well beyond 100 GHz and ˜30 GHz OE bandwidths are readily achievable with conventional Si waveguide PDs. Specifically, FIG. 1A-C illustrates a SiN MRR layer and Si absorbing layer within the same layer with a cross section view in different planes, whereby the same-layer material deposition of the absorbing photodetector layer 101 and SiN MRR layer 105 enforces the carrier transport axis to be parallel to the light propagation direction.

Therefore, as noted above, there is a need for a device design that allows high responsivity photodetection of VIS/NIR light without compromising the device speed.

### SUMMARY OF INVENTION

The various embodiments as described herein provide a cavity-enhanced photodetector for visible photonics.

In a first aspect, there is provided an integrated cavity-enhanced photodetector for visible light consisting of: a low-loss waveguide comprising a bus layer for input light and a Microring Resonator (MRR) layer; a photodetector layer which is formed underneath the MRR layer, a set of metal contacts connected to the edges of the photodetector layer that serve as an external contact of the photodetector: and a phase shifter coupled with the MRR layer and connected with a set of metal contacts.

In one embodiment of the first aspect, the bus layer and the MRR layer further comprise a low-loss silicon nitride (SiN) material.

In one embodiment of the first aspect, the photodetector layer comprises silicon device layer of a silicon-on-insulator (SOI) wafer or from silicon layer on silicon oxide deposited on silicon wafer.

In one embodiment of the first aspect, the phase shifter is a thermo-optic phase shifter made of a resistive Titanium Nitride (TiN) material.

In one embodiment of the first aspect, the photodetector has a unibody travelling-wave geometry or a travelling-wave photodetector array (TWPDA) structure.

In one embodiment of the first aspect, the light propagation axis in the MRR layer is orthogonal to the charge carrier transport axis in the photodetector layer.

In a second aspect, there is provided a process for fabricating an integrated cavity-enhanced photodetector for visible light comprising: forming a photodetector layer, forming a low-loss waveguide including a bus layer and an MRR layer: forming a first metal contact layer: forming a phase shifter: and forming a second metal contact layer, wherein the light propagation axis in the MRR layer is orthogonal to the charge carrier transport axis in the absorbing layer.

In one embodiment of the second aspect, the bus layer and the MRR layer comprise low-loss Silicon Nitride (SiN).

In one embodiment of the second aspect, the photodetector layer comprises Silicon material.

In one embodiment of the second aspect, the phase shifter is a thermo-optic phase shifter made of a resistive Titanium Nitride (TiN) material.

In one embodiment of the second aspect, the photodetector has a unibody travelling-wave geometry or a travelling-wave photodetector array (TWPDA) structure.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF DRAWINGS

Other objects, features, and advantages of the embodiment will be apparent from the following description when read with reference to the accompanying drawings. In the drawings, wherein like reference numerals denote corresponding parts throughout the several views:

The other objects, features and advantages will occur to those skilled in the art from the following description of the preferred embodiment and the accompanying drawings in which:

FIG. 1A-1C illustrate an isometric view of a conventional cavity-enhanced PD, made of SIN MRR and Si absorbing layer in the same layer (1A) with cross section view in different planes (1B and 1C);

FIG. 2A-2C illustrate a top view in the xz-plane (2A), a cross sectional view in the xy-plane (2B) and a cross-sectional view in the zy-plane (2C) of a cavity-enhanced unibody travelling-wave photodetector with a thermo-optic phase shifter, according to an embodiment herein:

FIG. 3 illustrates a top view of a cavity-enhanced travelling-wave photodetector array (TWPDA) structure, according to an embodiment herein;

FIGS. 4A and 4B illustrate an isometric view of a portion of the MRR layer and an absorbing layer made of (4A) silicon channel waveguide and (4B) silicon rib waveguide, according to an embodiment herein;

FIG. 5A-B illustrate doping profile to form an APD device and FIG. 5C denotes a profile to form an MSM PD device. (5A) P+-I-P-N+-N++ doping profile, or (5B) P++-P-N+-N++ doping profile, according to an embodiment herein:

FIG. 6 illustrates an isometric view of a cavity-enhanced PD made of SiN MRR and Si absorbing layer in different layers showing the light propagation and carrier transport axes, according to an embodiment herein;

FIG. 7 is a process flow of the fabrication of the photodetector disclosed herein; and

FIG. 8 is a process flow of the fabrication of the photodetector disclosed herein with additional intermediate steps to the process illustrated in FIG. 7.

To facilitate understanding, like reference numerals have been used, where possible to designate like elements common to the figures.

### DETAILED DESCRIPTION OF PREFERRED EMBODIMENTS

In the following detailed description, reference is made to the accompanying drawings that form a part hereof, and in which the specific embodiments that may be practiced is shown by way of illustration. The embodiments are described in sufficient detail to enable those skilled in the art to practice the embodiments and it is to be understood that the logical, mechanical, and other changes may be made without departing from the scope of the embodiments. The following detailed description is therefore not to be taken in a limiting sense.

Conventional photodetectors have the following issues that the photodetector disclosed herein aims to solve: 1) The butt-coupling used in conventional PDs suffers from high insertion loss: 2) the MRR-cavity-enhanced photodetector (PD) for NIR has non-orthogonal orientation of carrier transport and light propagation axes, limiting its OE bandwidth: 3) Interlayer-grating assisted PD does not report on photodetection capability on the coupled region: 4) Grating assisted PDs are not suitable for dense photonic integrated circuits: 5) The microring resonator-enhanced PDs with silicon input waveguide would cause significant propagation loss once they are operated at visible wavelengths, and if the absorbing region comprises Germanium then the device would suffer from higher dark current compared to silicon absorbing region due to its smaller band gap.

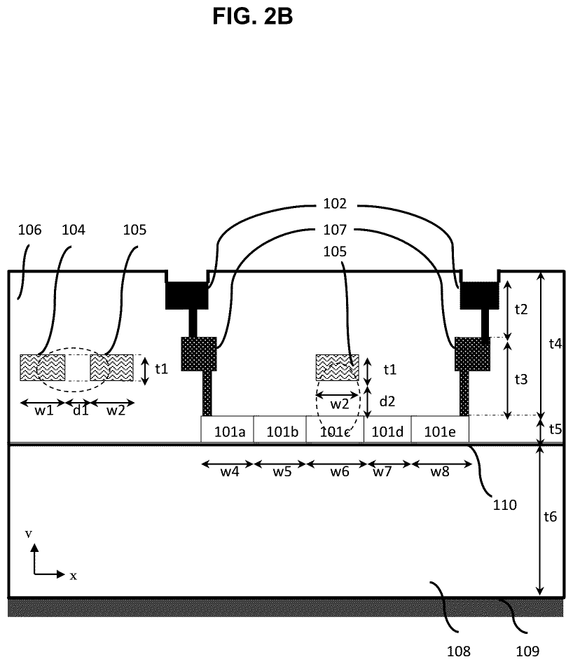

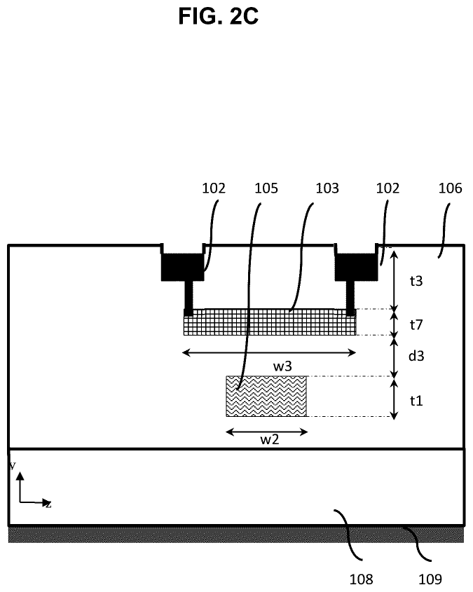

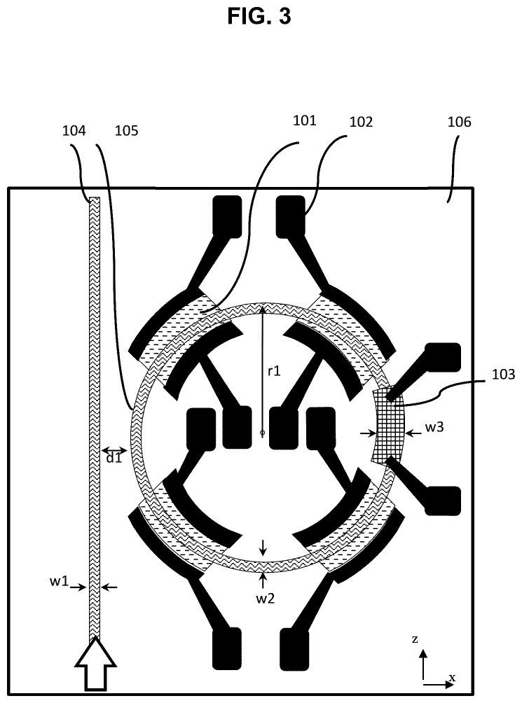

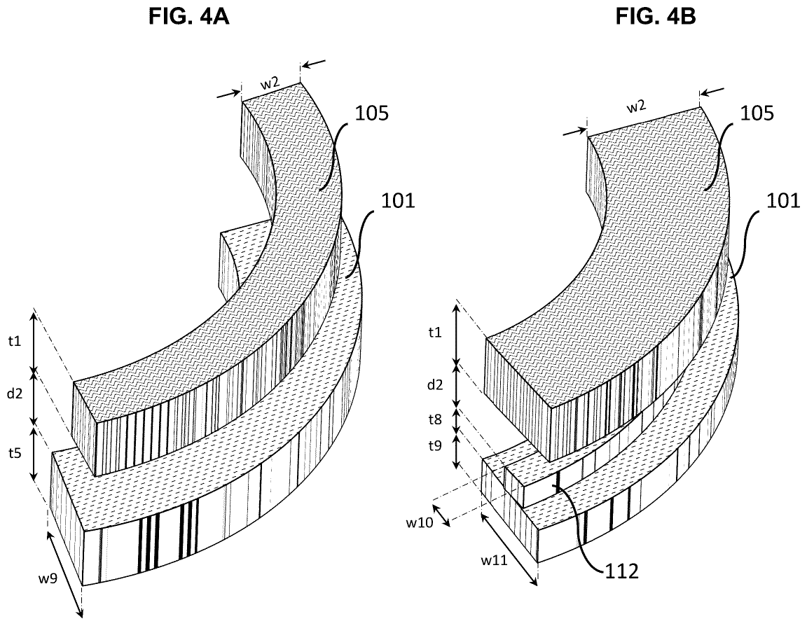

The present disclosure herein proposes an implementation of an integrated cavity-enhanced silicon nitride-on-silicon photodetector as illustrated in FIG. 2A-2C and FIG. 3.

In one embodiment, the photodetector 100 can include a low-loss waveguide, a photodetector layer 101 (i.e., absorbing waveguide layer), a set of metal contacts 102, 107, and a phase shifter 103.

In one embodiment, the waveguide can include two layers namely a bus layer 104 for input light routing and a microring resonator (MRR) layer 105 for resonant cavity enhancement effect. The bus waveguide and the MRR can be made of SiN material, which has low losses at visible wavelengths. Such a low loss material increases cavity lifetime of photons, and the photons can evanescently couple to underneath silicon absorbing layer during their multiple passes.

In one embodiment, the bus layer 104 can have a width (w1) in the range of about 0.3-0.6 μm. In one embodiment, the MRR layer 105 can have a width (w2) in the range of about 0.3-0.6 μm.

In one embodiment, the bus layer 104 and the MRR layer 105 can have a thickness (t1) in the range of about 0.15-0.25 μm.

In one embodiment, the bus layer 104 and the MRR layer 105 can be coupled to each other and fabricated over the photodetector layer 101. In particular, the MRR layer can be positioned adjacent to the bus layer within a distance (d1) with the silicon oxide cladding material 106 separating these layers. In one embodiment, the distance (d1) can be in the range of about 0.25-0.40 μm.

In one embodiment, an interlayer dielectric (IDL) can be included between the bus layer 104 and the MRR layer 105. This interlayer dielectric (IDL) can be fabricated of silicon oxide.

As shown in FIGS. 2A and 3, the MRR layer 105 can form a photonic resonator. In one embodiment, the radius (r1) of the microring structure can be in the range of about 20-100 μm. As will be appreciated, the MRR layer 105 can also be other shapes and types of photonic resonator structures such as racetrack, arc bend, disc resonators, and photonic crystal cavities.

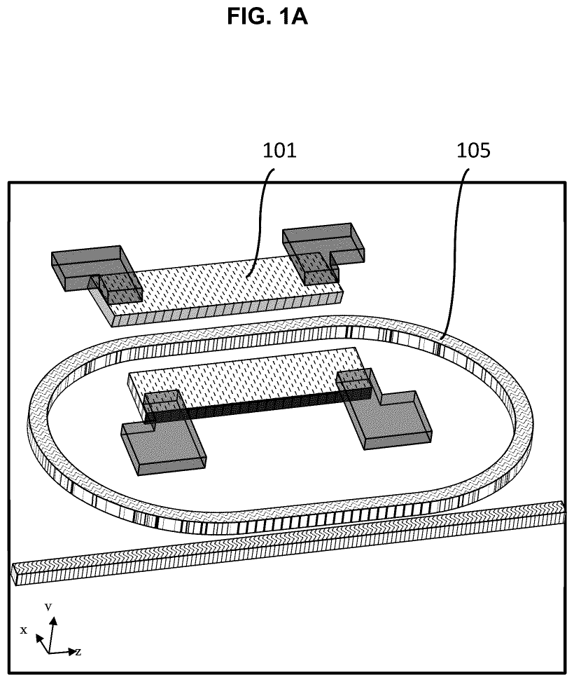

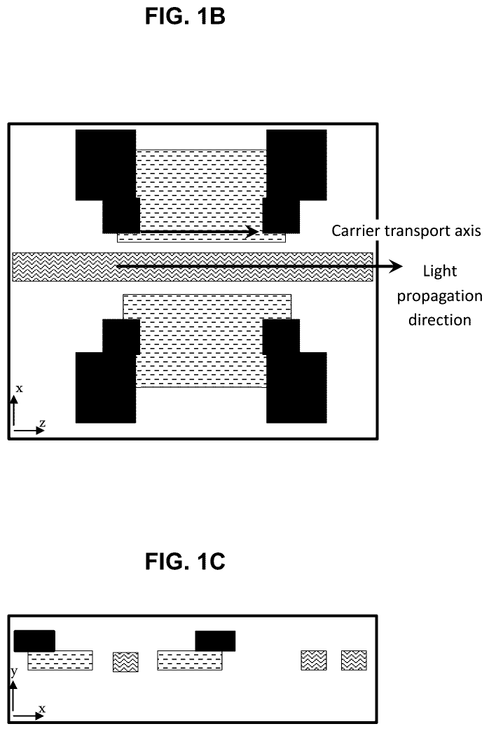

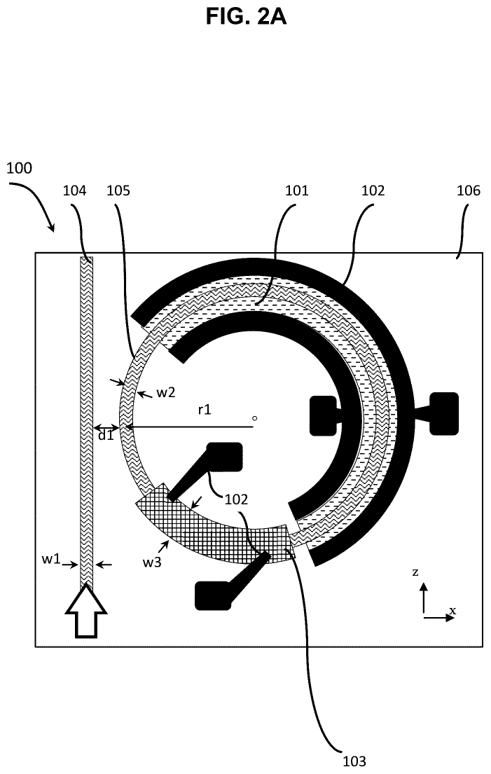

In one embodiment, the photodetector layer 101 can be formed underneath the MRR layer 105. Accordingly, the MRR layer 105 is on top of the photodetector layer 101 and they are not in the same layer as opposed to and in contrast with the conventional design of FIG. 1A-C.

In one embodiment, the photodetector layer 101 can be fabricated from silicon device layer of a silicon-on-insulator (SOI) wafer or from silicon layer on silicon oxide deposited on silicon wafer. The doping is performed on this photodetector layer 101 and the doped regions (p++, p+, p, n, n+, n++) and undoped regions (i.e., intrinsic) are shown in FIG. 2B as layers 101a-e. The layer 101 includes all these regions. The doping profile is as 111a as p++ ohmic contact, 101b as p-doped region, 101c as intrinsic region, and 101d as n-doped region, and 101e as n++ ohmic contact.

In one embodiment, the photodetector layer can have a width (w9) greater than or equal to about 2 μm.

As shown in FIG. 4A, the photodetector layer can be in a slab form without any rib section. In one embodiment, the photodetector layer can have a thickness (t5) of about 0.22 μm.

As shown in FIG. 4B, the photodetector layer can be of a rib waveguide structure positioned centrally with respect to the MRR layer. In one embodiment, the rib section 112 can have a width (w10) of about 0.15 μm. In one embodiment, the rib section can have a thickness (t8) of about 0.13 μm with a thickness (t9) of about 0.09 μm. In one embodiment, when interlayer coupling is performed between SiN and Si waveguides, the effective indices of the optical modes inside these two waveguides are matched, otherwise reflections occur due to index mismatch. Compared to a simple channel waveguide, a rib waveguide geometry can provide more freedom via additional design parameters such as rib etch depth (t8), rib width (w10) in order to tailor the effective index of silicon waveguide to match it with the effective index of SiN waveguide.

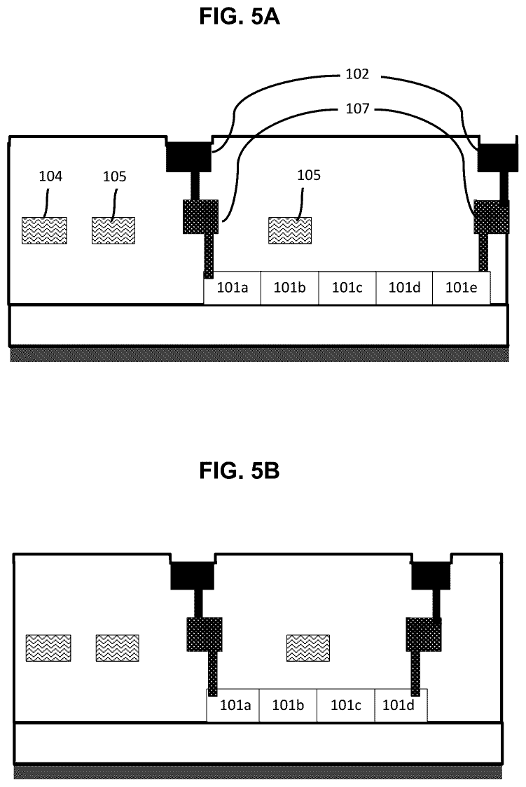

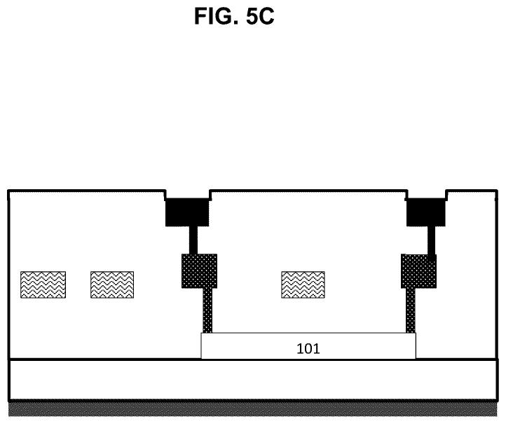

In one embodiment, the photodetector layer 101 can include one or more doped P-regions, an Intrinsic region and one or more doped N-regions. In one embodiment, the photodetector layer can include a combination of regions selected from a heavily doped P-region (p++), a moderately doped P-region (p+), a lightly doped P-region (p), an Intrinsic region, a lightly doped N-region (n), a moderately doped N-region (n+), and a heavily doped N-region (n++). In one embodiment, as shown in FIG. 5A, the photodetector layer 101 can be of separate absorption, charge, and multiplication (SACM) type doping profile, where photo absorption occurs in intrinsic region 101b and charge multiplication takes place in the junction formed by p-doped 101c and n+-doped 101d regions, with p++-doped 101a region and n++-doped region 101e serving as the ohmic contact to the junction. In one embodiment, as shown in FIG. 5B, the photodetector layer 101 can be of a p-n junction formed by a p-doped region 101b and a n+-doped region 101c with ohmic contacts formed by heavily doped p++ 101a and n++ 101d regions.

In one embodiment, as shown in FIG. 5C, the photodetector layer 101 can be of metal-semiconductor-metal photodetector formed by two Schottky contacts on the edges.

In one embodiment, each region in the photodetector layer 101 can have a width in the range of about 0.15-0.50 μm. In one embodiment, the p-doped regions and n-doped regions can have a width (w4, w5, w7, w8) of about 0.50 μm, and the Intrinsic region can have a width (w6) of about 0.15-0.50 μm, as shown in FIG. 2B.

In one embodiment, the photodetector layer can be coupled and positioned adjacent with the MRR layer. In particular, the MRR layer can be positioned above the photodetector layer to be adjacent by a distance (d2) with the silicon oxide cladding material 106 separating these layers. In one embodiment, the distance (d2) can be in the range of about 0.15-0.25 μm.

In one embodiment, the first set of metal contacts with contact points can be connected to the photodetector layer 101 and serve as an external contact of the photodetector.

In one embodiment, the set of metal contacts can include a first metal layer 107 and a second metal layer 102. In one embodiment, the first metal layer 107 can have a thickness (t3) of about 0.75 μm, and the second metal layer 102 can have a thickness (t2) of about 2 μm.

In one embodiment, the phase shifter 103 can be of a resistive metal heater. In one embodiment, the phase shifter can be coupled with the MRR layer 105 and connected with a second set of metal contacts 102.

In one embodiment, the phase shifter 103 can be coupled adjacent to and above the MRR layer 105, whereby a distance (d3) separates the phase shifter 103 and the MRR layer 105. In one embodiment, the distance (d3) can be about 0.80 μm. In this regard, the phase shifter 103 and the MRR layer 105 are separated by the cladding silicon oxide material 106.

The phase shifter 103 can be coupled adjacent to the MRR layer 105 for post-fabrication tuning of the spectral photoresponsivity of the photodetector by changing the resonance wavelength via thermo-optic effects. In one embodiment, the phase shifter can be a thermo-optic phase shifter made up of Titanium Nitride (TiN). Other types of resistive materials than titanium nitride (TiN) can include but not limited to Nickel Silicide (NiSi) and Chromium-Gold (Cr—Au) in SOI.

In one embodiment, a metal layer can be fabricated over the TiN layer to provide electrical power for thermo-optic tuning effect.

In one embodiment, the phase shifter 103 can have a width (w3) greater than or equal to about 2 μm. In one embodiment, the phase shifter 103 can have a thickness (t7) of about 0.12 μm.

In one embodiment, a cladding layer 106 can be included for the bus layer 104 and the MRR layer 105. This top cladding layer 106 can be fabricated of silicon oxide.

In one embodiment, the cladding layer 106 can have a thickness (t4) of about 2 μm.

Accordingly, in one embodiment, the integrated cavity-enhanced photodetector disclosed herein can consist of: a waveguide, comprising a bus layer for input light and a microring resonator (MRR) layer: a photodetector layer formed underneath the MRR layer, a first set of metal contacts connected to the photodetector layer to serve as an external contact of the photodetector: and a phase shifter coupled with the MRR layer and connected with a second set of metal contacts.

As shown in FIG. 2B, the photodetector layer 101 disclosed herein can be formed on a silicon device layer 110 which can have a thickness of about 220 nm. The silicon device layer 110 can be formed on top of a Buried Oxide (BOX) layer 108 which can have a thickness (t6) of about 2-3 μm and silicon handle substrate 109 underneath the BOX layer 108. In one example, the thickness of the silicon handle substrate can be 725 μm.

In FIGS. 2A-2C, the photodetector is configured in a unibody travelling-wave geometry for photodetection targeting applications such as optical power monitoring or analyte sensing, whereas in FIG. 3, the photodetector is configured as a travelling-wave photodetector array (TWPDA) with pre-compensated delay lines for high-saturation-power and high-speed photodetection targeting applications such as short-reach optical interconnects, visible light communication, and LIDAR.

Accordingly, in one embodiment the device can have a unibody travelling-wave electrode (FIG. 2A) or a travelling-wave photodetector array (TWPDA) structure (FIG. 3) that differs from the unibody PD form in that the device comprises an array of smaller photodetectors. Equipped with pre-compensated delay lines, the travelling-wave photodetector array (TWPDA) allows for high saturation power operation while retaining high OE bandwidth achieved by reduced depletion capacitance area.

As shown in FIG. 2B, a first metal contact 107 can be fabricated over a heavily doped P-region 101a while the other first metal contact 107 can be fabricated over a heavily doped N-region 101e and together they can form the ohmic contact to the photodetector layer 101. The second metal contact 102 can be fabricated over and on top of the first metal contact 107 thereafter and exposed to an external device connection. In one embodiment, both metal contacts can be fabricated in a pair.

The photodetector disclosed herein can also cover other photonic structures such as where the low-loss waveguiding is performed by another material instead of silicon nitride (stoichiometric Si₃N₄ or non-stoichiometric SiₓN_{y}). In one embodiment, the waveguiding materials include but not limited to titanium oxide (TiO₂), aluminium nitride (AlN), and aluminium oxide (Al₂O₃) materials.

The photodetector disclosed herein can have compatibility with photonic devices fabricated on CMOS-compatible SiN-on-SOI platform.

The photodetector disclosed herein can include (1) PIN photodiodes, shown in FIG. 2B, (2) avalanche photodiodes (APDs), shown in FIGS. 5A and 5B, and (3) MSM photodetectors, as shown in FIG. 5C.

As shown in FIGS. 5A and 5B, the doping profile of the photodetector layer can be modified for an APD device. In particular, FIG. 5A shows a I-P-N+ doping profile, whereas FIG. 5B shows a P-N+ doping profile with P++ and N++ forming the ohmic contacts in both device configurations. Optionally, a simpler metal-semiconductor-metal (MSM) photodetector as shown in FIG. 5C can be formed in case ion implantation is not feasible.

An APD can be realized by changing the width of doped regions and changing the doping concentrations therein. For instance, in FIG. 5A a conventional separate absorption, charge, and multiplication (SACM) type APD device can be realized by I (101b)-P (101c)-N+ (101d) doping profile where ohmic contacts are formed via heavily doped P++ (101a) and N++ (101e) regions. Here, the SiN MRR layer 105 can be placed over the intrinsic region (101b) and photogenerated electrons are swept through the multiplication region formed by the P (101c)-N+ (101d) junction. Alternatively, in FIG. 5B a simpler APD device where light absorption and multiplication occurs in the same depletion region can be realized by a P-N+ (101b-101c) doping profile where ohmic contacts are realized through heavily doped P++ (101a) and N++ (101d) regions. Here, the SiN MRR layer 105 can be asymmetrically placed over the p-n+ junction such that most of photoabsorption takes place inside the mostly depleted p-region.

In one embodiment, the photodetector disclosed herein can include the SiN MRR layer and Si absorbing layer within different layers and planes. In this embodiment, the light propagation axis in the MRR layer is orthogonal to the carrier transport axis in the absorbing layer, which results in a transit-time limited OE bandwidth that is independent of the photodetector length.

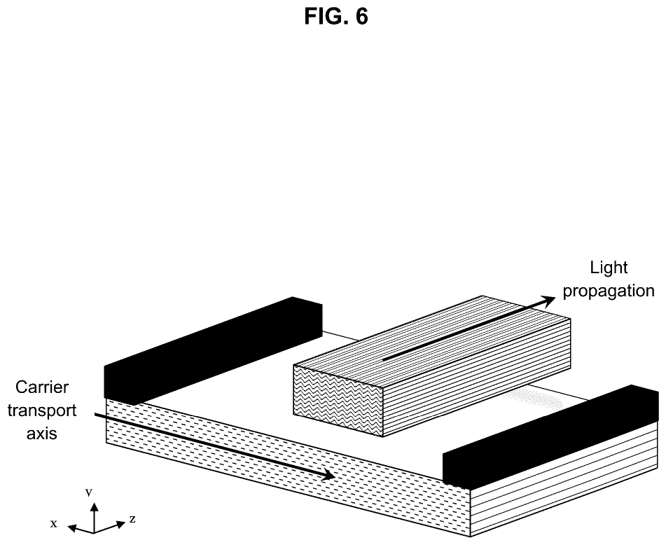

FIG. 6 illustrates an isometric view of a cavity-enhanced photodetector disclosed herein with the SIN MRR layer and Si absorbing layer being formed in different layers showing the light propagation and charge carrier transport axes. In this embodiment, a monolithic Si absorbing layer is formed underneath the MRR layer with its set of metal contacts oriented in a way that the charge carrier transport axis is orthogonal to the light propagation direction. This orientation allows for accommodating long coupling lengths to achieve high responsivity without deteriorating the device speed as the photogenerated charge carriers are collected across the shorter axis not along the light propagation direction as shown in FIG. 1. Moreover, this design allows for low-voltage operation because the depletion region width can be reduced to the order of photodetector width: this makes it possible to achieve avalanche photodiodes (APDs) with low operating voltages. Moreover, a smaller active device volume also reduces dark carrier generation.

Unlike the same-layer Si and SiN integration flow of FIG. 1A of conventional designs, the interlayer Si and SiN integration flow of the disclosed embodiments herein allows for achieving gaps of the order of a few tens of nanometres between waveguides by controlled thin-film deposition and subsequent etch steps. Thus, the light coupling from SiN waveguide to Si absorbing waveguide can be improved and the device responsivity can be increased.

Due to the interlayer coupling structure of the photodetectors disclosed herein and the device orientation, the photodetector length does not determine the transit-time limited bandwidth: thus, a high responsivity is achievable while maintaining high OE bandwidth. Further, the photodetector length can be changeable and made arbitrarily long to satisfy the required coupling condition of MRR-photodetector coupled system until the RC-limited bandwidth becomes dominant.

The present embodiment proposes a PIN photodetector formed 0.15 μm underneath a 0.5-μm wide SiN channel waveguide, as illustrated in FIG. 2B. The photodetector has a depletion region width W of ˜0.5 μm that is equal in length with the intrinsic region 101c of the PIN diode, and its electrodes are separated by 3 μm. The electrons reach their saturation velocity of υ_{d}=˜1×10⁷ cm/s at field strengths of |E|=1×10⁵ V/cm in silicon at room temperature so that the photodetector can operate at a reverse bias voltage of V_{B}≤10V.

Assuming a PIN photodetector, the transit time can be approximately τₜᵣ=W/_{υd}=˜5 ps, corresponding to a transit-time limited bandwidth fₜᵣ=0.443/τₜᵣ≈πGHZ. This structural specification means more than one order of magnitude transit-time limited bandwidth improvement over the conventional photodetectors which lack such orthogonality principle.

Unlike optical communication wavelength bands (e.g., O-band, C-band), there are no standard wavelength bands defined in the visible spectrum. In this regard, the integrated cavity-enhanced photodetector structures disclosed herein can be equipped with thermo-optic phase shifters on the MRR section to tailor the spectral responsivity of the photodetector. This is especially useful for integrated wavelength-division multiplexing (WDM) circuits for short-reach optical interconnects, lab-on-chip applications where different analytes have different absorption spectrum, and integrated quantum photonics where different quantum emitters emit their photons at different wavelengths. Such post-fabrication tuning capability allows for utilizing the same device for different photodetection needs.

The present invention uses SiN waveguide for low-loss optical waveguiding and passive functionalities for VIS/NIR light, and it couples the light to underneath the Si absorbing layer through thermally-tunable SiN MRR should an on-chip photodetection be needed.

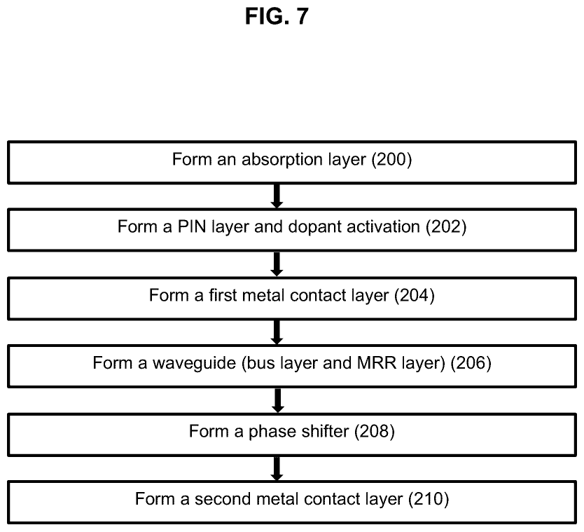

In one embodiment, there is provided a process for fabricating an integrated cavity-enhanced photodetector for visible photonics. As shown in FIG. 7, the process can comprise the following general steps.

At step 200, a photodetector layer can be patterned. The photodetector layer can be defined as a Si slab using photolithography (PL) and inductively coupled plasma (ICP) etch. In addition, a Si rib section can be formed using lithography and ICP etching with an oxide hard mask to pattern the Si rib section. The photodetector layer can be formed on a silicon device layer of a silicon-on-insulator (SOI) substrate.

At step 202, a photodetector layer can be formed with ion implantation and subsequent dopant activation steps. In particular, a pad oxide can be deposited by PECVD, followed by photolithography (PL) and subsequent ion implantation steps to form p-type and n-type regions. Similarly, p++ and n++ ohmic contacts can be formed, followed by dopant activation by rapid thermal annealing (RTA). Subsequently, PECVD oxide can be deposited as a first interlayer dielectric (ILD1), followed by vias (connector) formation using PL and dry etch steps.

At step 204, a first metal contact layer can be fabricated. In particular, following wet cleaning, the first metal contact layer can be formed with TaN/Al/TaN deposition and subsequent PL and dry etch steps. The first metal contact layer is in contact with the photodetector layer at p++ and n++ doped regions. Thereafter, PECVD oxide deposition and CMP for planarization follow.

At step 206, a low-loss waveguide comprising a bus layer and an MRR layer can be fabricated. In particular, an oxide etch step is performed to remove the oxide covering the Si absorbing region prior to SiN deposition. A PECVD SiN deposition can be implemented followed by PL and ICP etching steps to pattern the SiN bus layer and MRR layer.

At step 208, a phase shifter can be fabricated. In particular, TiN is deposited with the following PL and dry etch steps to form the resistive phase shifter. The phase shifter can be formed to be coupled with the MRR layer and can be connected with a metal contact layer. A second interlayer dielectric (ILD2) is deposited, followed by vias (connector) formation using PL and dry etch steps.

At step 210, a second metal contact layer can be fabricated. In particular, the second metal contact layer can be formed by TaN/Al deposition followed by PL and etch steps. An oxide layer can be deposited as a passivation layer. PL and dry etch steps can follow for bond pad opening for external contact of the photodetector.

Accordingly, in one embodiment, there is provided a process for fabricating an integrated cavity-enhanced photodetector for visible photonics that can comprise the following steps: forming a photodetector layer: doping photodetector layer with ion implantation; forming a first metal contact layer: forming a low-loss waveguide including a bus layer and a MRR layer: forming a phase shifter: and forming a second metal contact layer, wherein the light propagation axis in the MRR layer is orthogonal to the carrier transport axis in the absorbing layer.

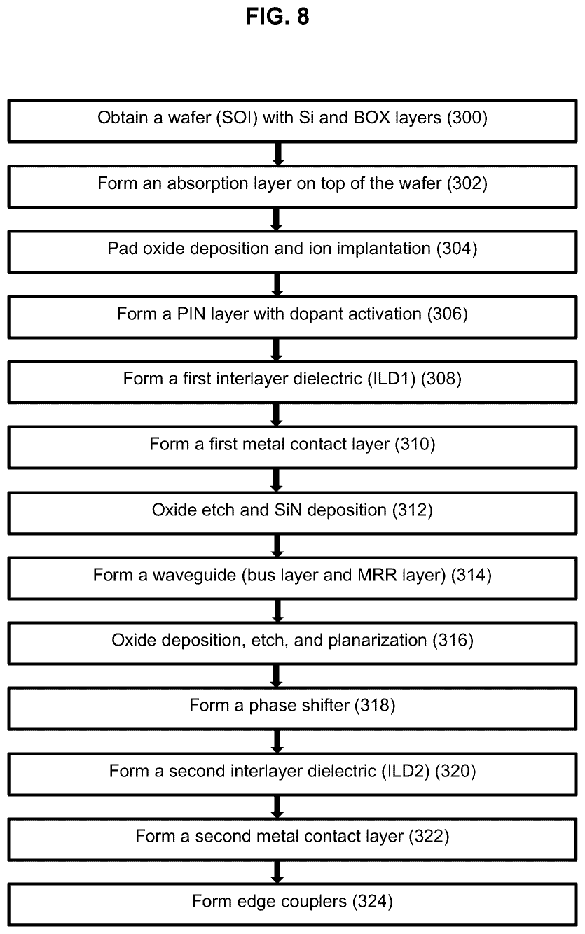

As shown in FIG. 8, the process outlined in FIG. 7 can comprise additional intermediate steps, as follows.

At step 300, a wafer (SOI) can be obtained to begin with. In particular, an 8-inch SOI wafer with 220 nm Si device layer and 3 μm buried oxide (BOX) layers can be used.

At step 302, a photodetector layer can be formed in the silicon device layer of an SOI wafer. The photodetector layer can be defined as a Si slab using Photolithography (PL) and Inductively Coupled Plasma (ICP) etch. In addition, a Si rib section can be formed using lithography and ICP etching with an oxide hard mask to pattern the Si rib section.

At step 304, a pad oxide can be deposited on the photodetector layer by PECVD prior to ion implantation. This is followed by boron and phosphorus implantation to form the p-type and n-type regions in the photodetector layer, respectively. Similarly, p++ and n++ ohmic contacts can be formed with similar ion implantation steps.

At step 306, the dopant activation of doped regions of the photodetector layer is performed by rapid thermal annealing (RTA). Thereafter, pad oxide is stripped using a Dilute Hydrofluoric acid etchant (DHF).

At step 308, oxide can be deposited by PECVD as a first interlayer dielectric (ILD1), followed by vias (connector) formation using PL and dry etch steps.

At step 310, a first metal contact layer can be fabricated. In particular, following wet cleaning, the first metal contact layer can be formed with TaN/Al/TaN deposition and subsequent PL and dry etch steps. The first metal contact layer is in contact with the photodetector layer at p++ and n++ doped regions. Thereafter, PECVD oxide deposition and CMP for planarization follow.

At step 312, an oxide etch step is performed to remove the oxide covering the relevant photodetector region prior to SiN deposition. Thereafter, SiN is deposited by PECVD.

At step 314, a SiN waveguide, including a bus layer and a MRR layer can be fabricated. In particular, SiN film can be patterned to form SiN bus waveguide and MRR layer by PL and ICP etching steps.

At step 316, an oxide can be deposited by PECVD followed by backside SiN etching and blanket oxide etching steps. This is followed by CMP for oxide planarization.

At step 318, a thermo-optic phase shifter can be fabricated. In particular, TiN can be deposited with subsequent PL and dry etch steps to form the resistive phase shifter. The phase shifter can be formed to be coupled with the MRR layer and can be connected with a metal contact layer.

At step 320, PECVD oxide can be deposited as a second interlayer dielectric (ILD2), followed by vias (connector) formation using PL and dry etch steps.

At step 322, a second metal contact layer can be fabricated. In particular, the second metal contact layer can be formed by TaN/Al deposition followed by PL and etch steps. A PECVD oxide layer can be deposited as a passivation layer. PL and dry etch steps can follow for bond pad opening. The second metal contact layer is connected to the first metal contact layer such that both these metal contacts serve as an external contact of the photodetector.

At step 324, deep trenches can be made to form edge couplers.

It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the claim.

1. An integrated cavity-enhanced photodetector for visible photonics comprising:
a substrate and a top cladding layer positioned on the substrate;
a waveguide, comprising a bus layer for input light, and a microring resonator layer;
a photodetector layer, which is separated from the microring resonator layer;
a first set of metal contacts, which are connected to the photodetector layer and serve as an external contact; and
a phase shifter, wherein the phase shifter is coupled with the microring resonator layer and the phase shifter is connected to a second set of metal contacts;
wherein the microring resonator layer is positioned between the phase shifter and the photodetector layer, and the photodetector layer is closer to the substrate than the microring resonator layer.

2. The photodetector of claim 1, wherein the bus layer and the microring resonator layer comprise a Silicon Nitride (SiN), the photodetector layer comprises Silicon, and the phase shifter comprises Titanium Nitride (TiN).

3. The photodetector of claim 1, wherein the microring resonator layer and the phase shifter are positioned in the top cladding layer.

4. The photodetector of claim 1, wherein the substrate further comprises a buried oxide layer positioned in direct contact with the top cladding layer.

5. The photodetector of claim 4, wherein photodetector layer is positioned directly on the buried oxide layer, and the first metal contacts extend from the photodetector layer to a top of the top cladding layer.

6. The photodetector as claimed in claim 1, wherein the microring resonator layer is separated from the photodetector layer by 0.15 μm to 0.25 μm, and the top cladding layer is positioned between the microring resonator layer and the photodetector layer.

7. An integrated cavity-enhanced photodetector for visible photonics comprising:
a substrate and a top cladding layer positioned on the substrate;
a waveguide, comprising a bus layer for input light, and a microring resonator layer;
a photodetector layer, which is formed below the microring resonator layer;
a first set of metal contacts, which are connected to the photodetector layer and server as an external contact; and
a phase shifter, wherein the phase shifter is separated from the microring resonator layer by a distance, and the phase shifter is connector to a second set of metal contacts;
wherein the microring resonator layer is positioned between the phase shifter and the photodetector layer, and the photodetector layer is closer to the substrate than the microring resonator layer.

8. The photodetector of claim 7, wherein the photodetector comprises a (p++) ohmic contact, a p-doped region, an intrinsic region, an n-doped region, and an n-doped (n++) ohmic contact; and
one of the first set of metal contacts is attached to the photodetector layer at the p++ ohmic contact, and the other of the first set of metal contacts is attached to the photodetector layer at the n++ ohmic contact.

9. The photodetector of process of claim 7, wherein the microring resonator layer has a uniform cross section.

10. The photodetector of claim 7, wherein the photodetector layer has one of a slab or rib waveguide structure extending toward the microring resonator layer.

11. The photodetector of claim 7, wherein the photodetector comprises one of a PIN photodiode, an avalanche photodiode, and a metal-semiconductor-metal photodetector.

12. The photodetector of claim 1, wherein a light propagation axis in the microring resonator layer is orthogonal to a carrier transport axis in the photodetector layer.
